(19) United States
(12) Patent Application Publication
(10) Pub. No.: US 2010/0225011 A1
(43) Pub. Date: Sep. 9, 2010

(54) System and Method for Integrated Circuit Fabrication

(75) Inventors: Bo-I Lee, Sindian (TW); Tsung-Ding Wang, Tainan (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd., Hsin-Chu (TW)

(21) Appl. No.: 12/683,528

(22) Filed: Jan. 7, 2010

Related U.S. Application Data
(60) Provisional application No. 61/157,935, filed on Mar. 6, 2009.

(51) Int. Cl. H01L 23/544; H01L 21/687

(52) U.S. Cl. 257/797; 269/208; 257/E23.179

(57) ABSTRACT

A system and method for integrated circuit fabrication is provided. A wafer holding system includes a wafer carrier that holds the wafer at a specified alignment, and a top ring disposed on a top surface of the wafer and of the wafer carrier. The top ring holds the wafer and the wafer carrier together as a single unit. The wafer carrier includes an alignment mechanism to hold the wafer in the specified alignment.

This application claims the benefit of U.S. Provisional Patent Application Ser. No. 61/157,935, filed on Mar. 6, 2009, and entitled “System and Method for Integrated Circuit Fabrication,” which application is incorporated herein by reference.

### TECHNICAL FIELD

The present invention relates generally to integrated circuits, and more particularly to a system and method for integrated circuit fabrication.

### BACKGROUND

Integrated circuits have had an impact in practically every aspect of modern life. They have enabled products ranging from computers, video equipment, audio equipment, automobiles, appliances, and so forth, to become more reliable and feature filled while being less expensive at the same time.

The manufacture of integrated circuits involves the fabrication of the integrated circuits on a substrate that is initially a part of a wafer, which may subsequently be cut into individual dice. As fabrication techniques have evolved, the wafers have become both larger and thinner. The size and thinness of the wafers may make them more difficult to handle without damaging them or without incurring additional expense due to elaborate handling techniques.

FIG. 1a is a diagram illustrating an isometric view of a system 100 used to handle large and thin wafers. System 100 includes a wafer 105 that may be attached to a wafer carrier 110 using an adhesive 115. Adhesive 115 may have the shape of wafer 105, as shown in FIG. 1a, or adhesive 115 may be in the form of linear strips, e.g., shaped like normal adhesive tape strips. Adhesive 115 may be applied to wafer carrier 110 and then wafer 105 may be positioned on top of adhesive 115 and wafer carrier 110. Alternatively, adhesive 115 may be applied to wafer 105 and then wafer 105 may be positioned on wafer carrier 110. In yet another alternative, adhesive 115 may be spun on wafer carrier 110 and then allowed to dry or cure before wafer 105 is positioned on wafer carrier 110. FIG. 1b is a diagram illustrating a side view of system 100.

Preferably, adhesive 115 possesses adequate cohesive properties to firmly hold wafer 105 to wafer carrier 110 while wafer 105 undergoes fabrication. Additional requirements may include the ability to retain adhesive properties while undergoing any high or low temperature processing required in fabrication. However, the cohesive properties of adhesive 115 should not be so great that removing wafer 105 from wafer carrier 110 will be difficult once fabrication is complete. Furthermore, adhesive 115 should not leave residue that may require additional cleaning steps once wafer 105 has been removed. Also, the removal of wafer 105 should be relatively easy, with little chance of damaging wafer 105. So far, existing adhesive tapes and materials do not meet the requirements.

### SUMMARY OF THE INVENTION

These and other problems are generally solved or circumvented, and technical advantages are generally achieved, by embodiments of a system and a method for integrated circuit fabrication.

In accordance with an embodiment, a wafer holding system is provided. The wafer holding system includes a wafer carrier configured to hold the wafer at a specified alignment, and a top ring disposed on a top surface of the wafer and of the wafer carrier. The wafer carrier having an alignment mechanism to hold the wafer in the specified alignment, and the top ring configured to hold the wafer and the wafer carrier together as a single unit.

In accordance with another embodiment, a system is provided. The system includes a base unit formed of a first material having a coefficient of thermal expansion (CTE) substantially equal to that of a wafer disposed on a top surface of the base unit, and a ring having a cylindrical flange extending at least part way down over the base unit to fit over the wafer and the base unit, and a lip formed around a top surface of the ring to prevent the base unit from extending more into the ring than specified. The base unit having an alignment mechanism to maintain a specified alignment of the wafer, and the ring formed of a second material having a CTE about equal to that of the wafer.

In accordance with another embodiment, a wafer for use with a wafer carrier having an alignment mechanism to hold the wafer in a specified alignment is provided. The wafer includes a circular disc with a plurality of alignment openings formed in an annular ring about a periphery of the wafer. The alignment pillars at least in part passes through the alignment openings when the wafer is placed onto the wafer carrier to hold the wafer in alignment. Each alignment opening is slightly larger than an alignment pillar, and there are at least as many alignment openings as there are alignment pillars.

An advantage of an embodiment is that adhesives are not required to fix a wafer to a wafer carrier. With no adhesives used, there is no adhesive residue to remove after fabrication is complete. Additionally, there is no concern with adhesive breakdown at elevated fabrication temperatures.

A further advantage of an embodiment is that the fabrication costs may be reduced since adhesives are not required. Furthermore, since adhesives are not used, additional fabrication steps that may be required to apply the adhesives and to remove the adhesives are not required.

Yet another advantage of an embodiment is that the embodiments allow for reuse, which can further help reduce cost as well as waste.

The foregoing has outlined rather broadly the features and technical advantages of the present invention in order that the detailed description of the embodiments that follow may be better understood. Additional features and advantages of the embodiments will be described hereinafter which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the embodiments, and the advantages thereof, reference is now made to the following descriptions taken in conjunction with the accompanying drawings, in which:

FIG. 1a is an isometric view of a prior art system used to handle large and thin wafers;

FIG. 1b is a side view of a prior art system used to handle large and thin wafers;

FIG. 2a is an isometric view of a wafer holding system;

FIG. 2b is a side view of the wafer holding system;

FIG. 2c is an isometric view of the wafer holding system assembled into a single unit;

FIG. 2d is a side cross-sectional view of the wafer holding system assembled into a single unit;

FIG. 3a is an isometric view of a wafer holding system;

FIG. 3b is an isometric view of a wafer holding system;

FIG. 3c is a side cross-sectional view of a wafer holding system;

FIG. 3d is an isometric view of a wafer carrier;

FIG. 3e is an isometric view of a wafer and a wafer carrier;

FIG. 3f is a top view of a wafer and a wafer carrier;

FIG. 3g is a side cross-sectional view of a wafer holding system;

FIG. 3h is a side cross-sectional view of a wafer holding system;

FIG. 3i is a side cross-sectional view of a wafer holding system;

FIGS. 4a through 4l are diagrams illustrating the fabrication of integrated circuits using a top die bonding technique;

FIG. 5a is a flow diagram of the fabrication of an integrated circuit; and

FIG. 5b is a flow diagram of the placement of a wafer in a wafer holding unit.

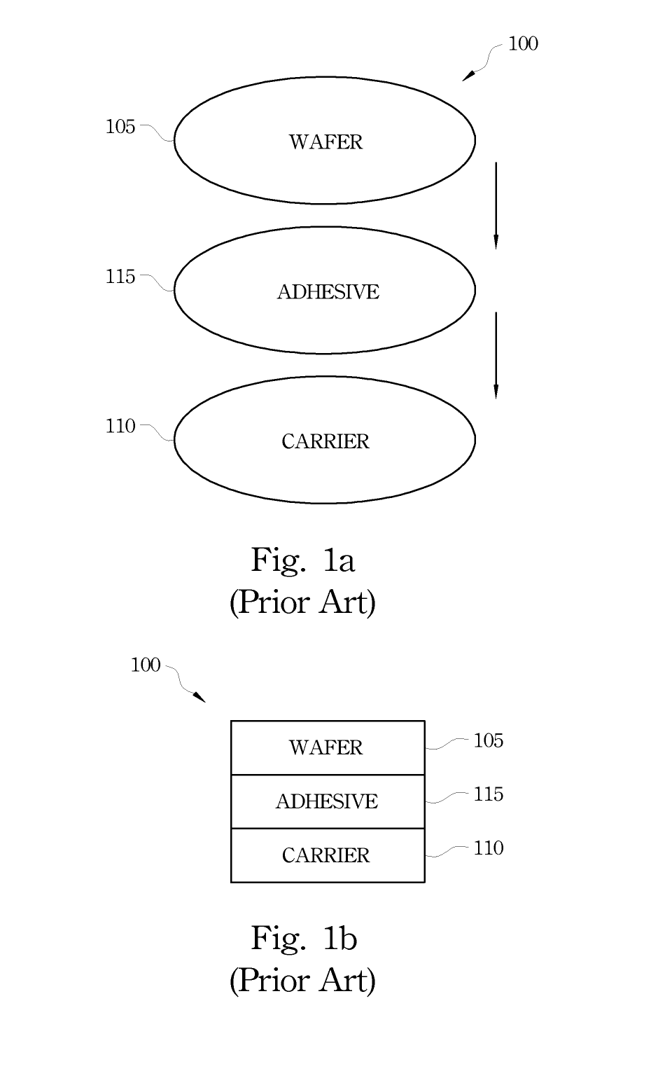

### DETAILED DESCRIPTION OF ILLUSTRATIVE EMBODIMENTS

The making and using of the embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The embodiments will be described in a specific context, namely integrated circuits fabricated using top die bonding. The invention may also be applied, however, to other integrated circuit fabricated using other fabrication techniques, wherein there is a need to maintain alignment of a wafer whereon the integrated circuits are created.

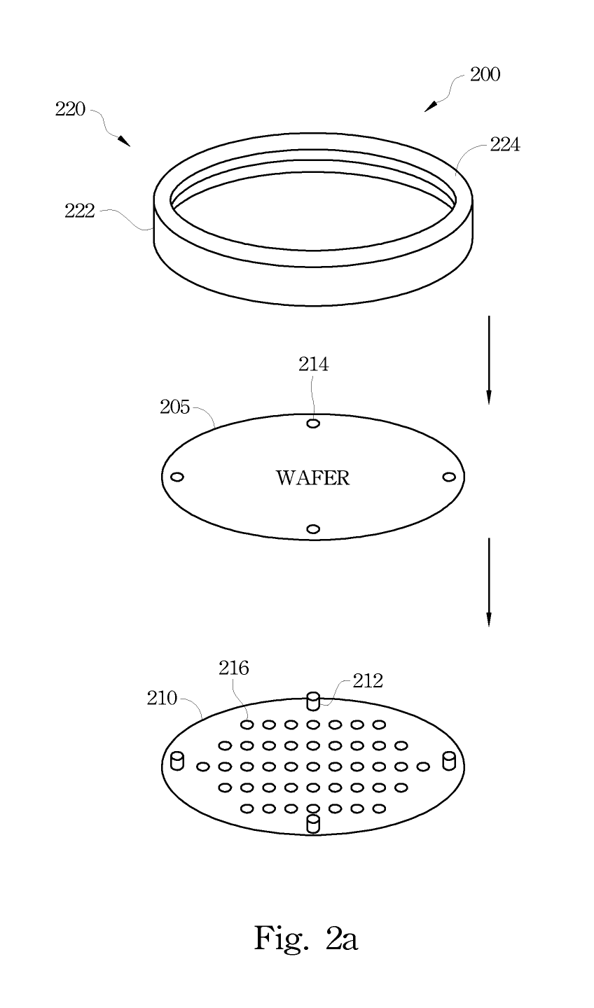

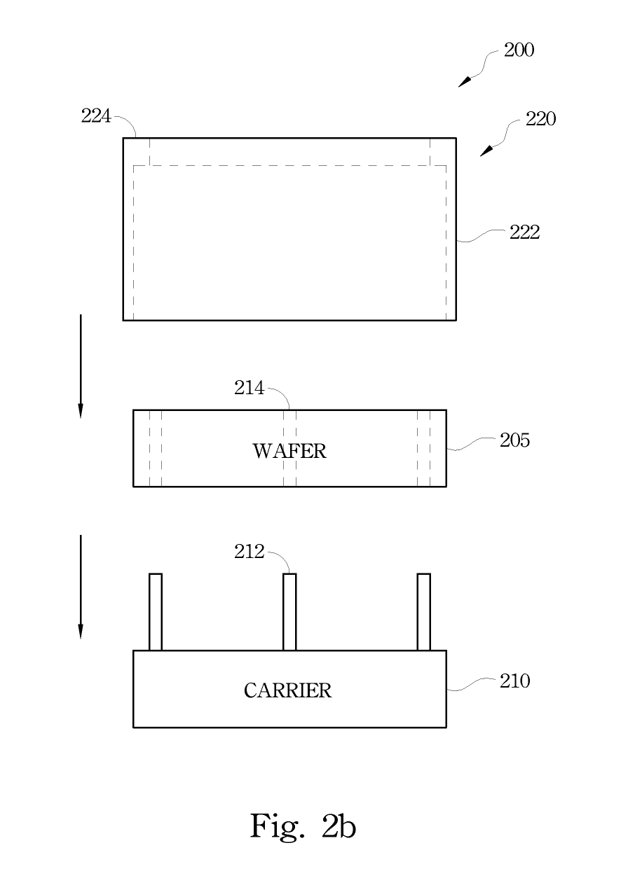

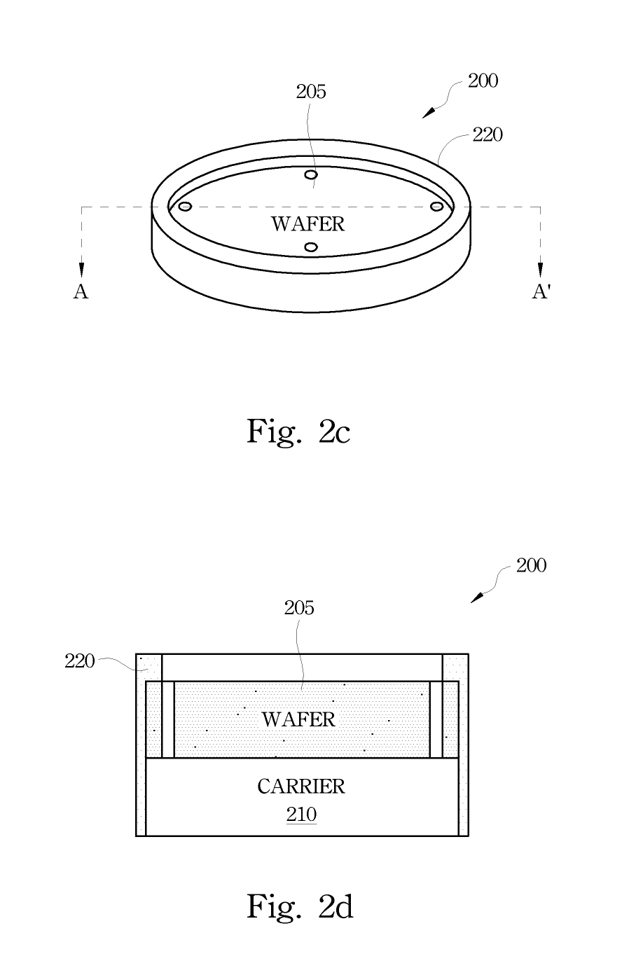

FIG. 2a is a diagram illustrating an isometric view of a wafer holding system 200 used to mount a wafer 205 for fabrication. According to an embodiment, wafer 205 may be positioned in a wafer carrier 210 to enable easy and safe handling of wafer 205 during fabrication of integrated circuits on wafer 205.

In order to facilitate accurate alignment of wafer 205 in wafer carrier 210, wafer carrier 210 may feature a number of alignment pillars, such as alignment pillar 212. Wafer 205 may include a number of holes, such as hole 214, which may allow the alignment pillars to pass through and hold wafer 205 in alignment with respect to wafer carrier 210. The holes in wafer 205 may be formed by drilling, notching, etching, and so forth. According to an embodiment, wafer carrier 210 may include at least two alignment pillars. In general, there may be no limit to the number of alignment pillars on wafer carrier 210 with exception of physical space available for the alignment pillars. However, too many alignment pillars may be difficult to create and it may be difficult to align wafer 205 to wafer carrier 210 if wafer carrier 210 includes a large number of alignment pillars. Furthermore, too many holes formed through wafer 205 may weaken wafer 205. Although shown as having a cylindrical shape, alignment pillars may have other cross-sectional shapes, including triangular, square, pentagonal, hexagonal, oval, and so forth. The shape of the alignment pillars may have an impact on the shape of the holes in wafer 205.

Furthermore, the alignment pillars may be positioned along an outer periphery of wafer carrier 210 so that the holes in wafer 205 may be in an exclusion area of wafer 205. This may help to reduce the impact of the holes on the useful surface area of wafer 205. Preferably, there may be one hole in wafer 205 for each alignment pillar in wafer carrier 210. However, there may be more holes in wafer 205 than alignment pillars. Providing holes in excess of alignment pillars may enable the use of different wafer carriers to increase flexibility. For example, a wafer 205 with six holes may be used with wafer carriers having two, three, four, five, or six alignment pillars.

Wafer carrier 210 may also include a plurality of vacuum holes, such as vacuum hole 216, formed through its surface. The vacuum holes may allow for a vacuum to be created between wafer 205 and a fabrication station to firmly fix wafer 205 (and wafer holding system 200) in place during a fabrication operation. Generally, since feature size of modern integrated circuits are on the order of nanometers, any movement or slippage of wafer holding system 200 may result in irreparable damage to integrated circuits formed on wafer 205. Therefore, it may be desirable to fix wafer 205 and wafer holding system 200 as firmly as possible during fabrication.

Wafer holding system 200 also includes a top ring 220 that may be positioned over wafer 205 and wafer carrier 210. According to an embodiment, top ring 220 includes a cylindrical flange 222 that may fit snugly around wafer 205 and wafer carrier 210 to help ensure that wafer 205 does not move significantly once top ring 220 is in place. Top ring 220 also includes a lip 224 formed about a top edge of top ring 220 to prevent top ring 220 from sliding down further over wafer 205 and wafer carrier 210 than intended. Top ring 220 may attach to wafer carrier 210 by friction or some physical attachment, such as pins, latches, screws, tapered surfaces, and so forth.

Wafer carrier 210 and top ring 220 may be made from materials having a coefficient of thermal expansion (CTE) that is equal to or substantially equal to the CTE of wafer 205. Matching the CTE may allow wafer 205, wafer carrier 210, and top ring 220 to expand and contract with relative uniformity as the temperature changes. If materials with substantially different CTEs are used, then undesired stress may be placed on wafer 205, which may cause wafer 205 to distort, warp, crack, or break.

FIG. 2b is a diagram illustrating a side view of wafer holding system 200 as shown in FIG. 2a. As shown in FIG. 2b, dimensions of wafer 205, wafer carrier 210, and top ring 220 may be exaggerated to simplify the illustration. Also shown in FIG. 2b as dotted lines are hidden features of wafer 205 (for example, hole 214) and top ring 220 (for example, interior surface of top ring 220). Cylindrical flange 222 and lip 224 are also shown. In order to maintain simplicity, vacuum holes in wafer carrier 210 are not shown.

FIG. 2c is a diagram illustrating an isometric view of wafer holding system 200, wherein components of wafer holding system 200 (wafer 205, wafer carrier 210, and top ring 220) are assembled into a single unit. As shown in FIG. 2c, wafer carrier 210 is enclosed within top ring 220 and may not be visible. In alternate embodiments, top ring 220 may not completely enclose wafer carrier 210 and wafer carrier 210 may be partially visible.

FIG. 2d is a diagram illustrating a side view of wafer holding system 200, wherein wafer holding system 200 has been sliced along line A-A′ as shown in FIG. 2c. As shown in FIG. 2d, alignment pillars of wafer carrier 210 fit within holes in wafer 205 and both wafer 205 and wafer carrier 210 fit within top ring 220. Although shown to end in alignment with a top surface of wafer 205, alignment pillars may extend above wafer 205 or not extend the full thickness of wafer 205.

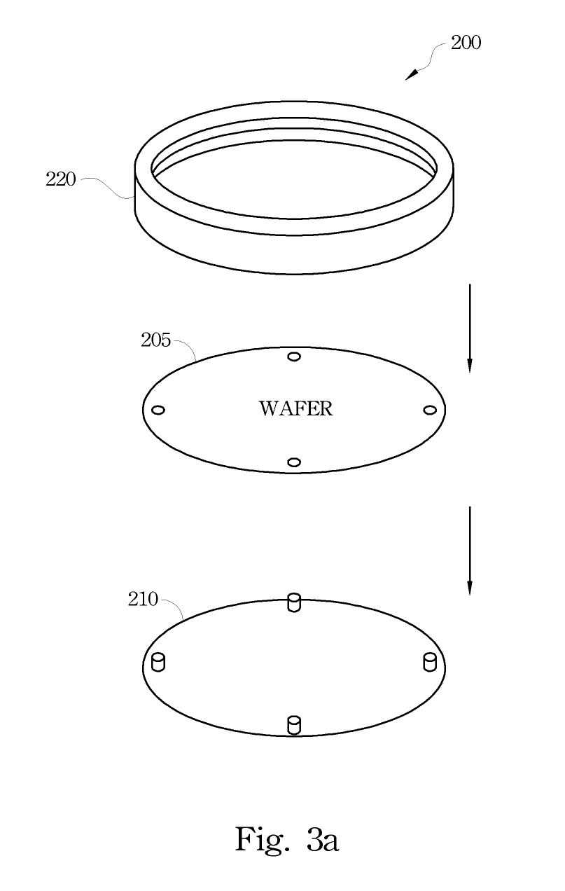

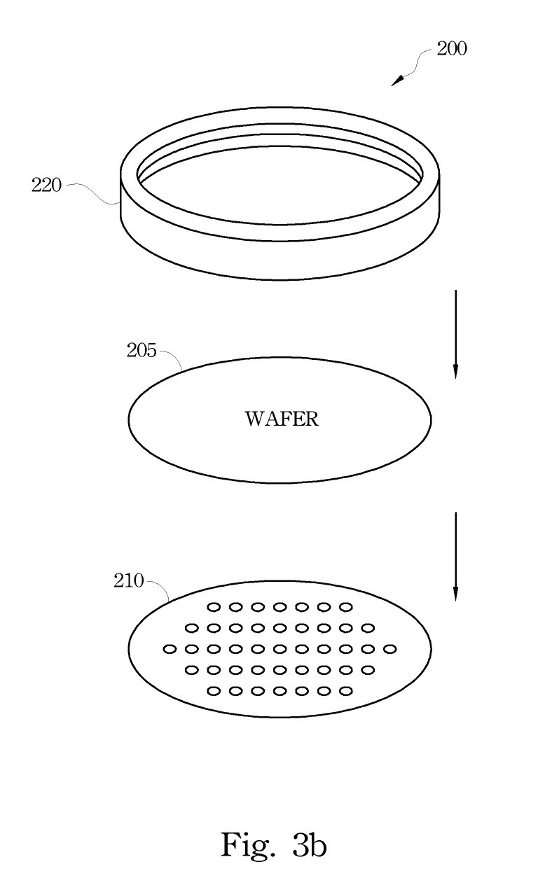

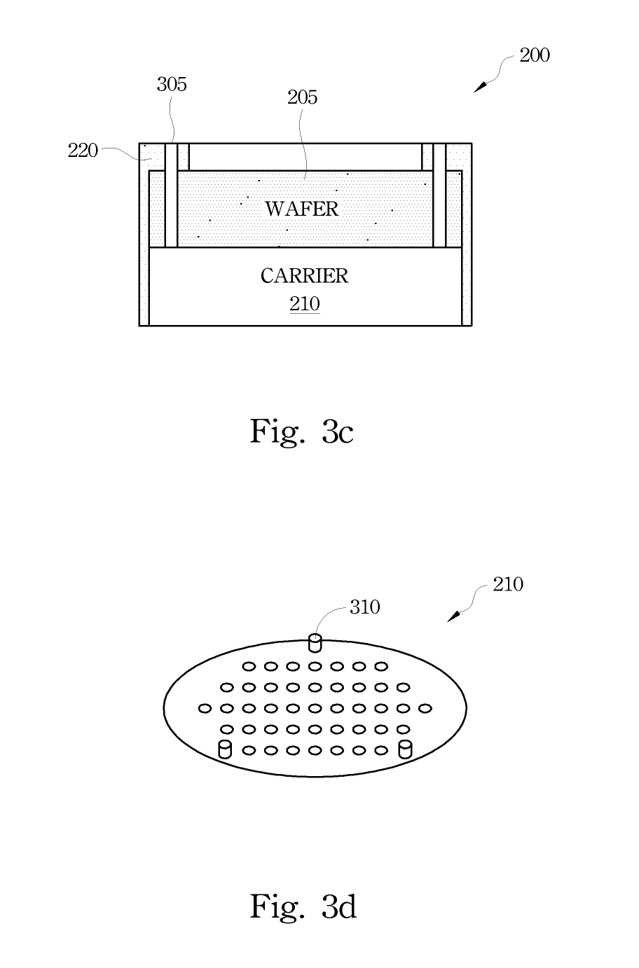

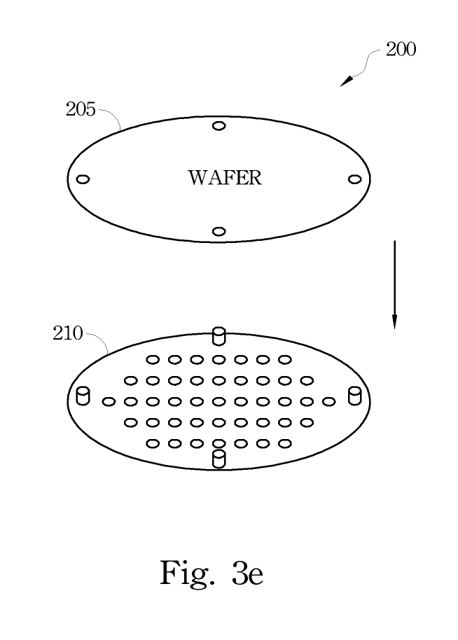

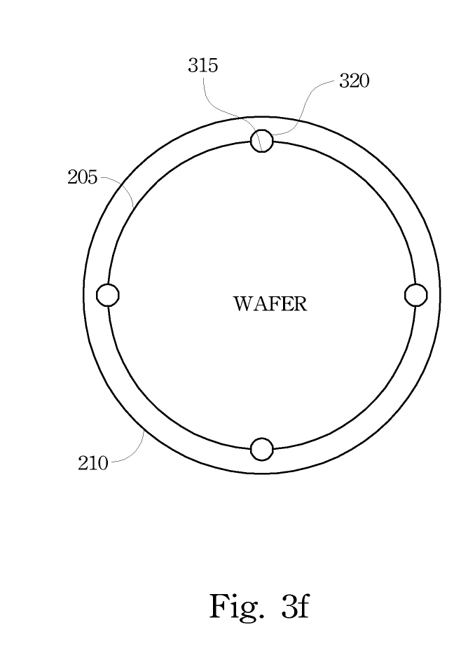

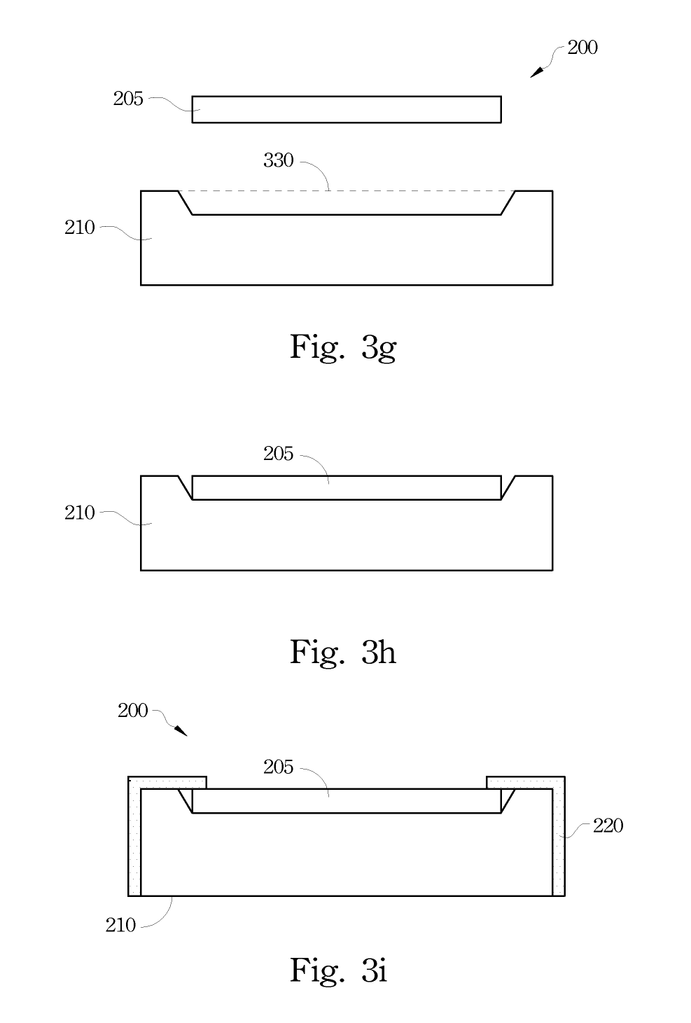

FIG. 3a is a diagram illustrating an isometric view of wafer holding system 200. FIG. 3a illustrates an alternate embodiment of wafer carrier 210, wherein wafer carrier 210 does not feature vacuum holes. With an adequate number of alignment pillars and if holes created in wafer 205 are sufficiently precise, the combination of the alignment pillars and the holes may be sufficient to prevent wafer 205 from moving once wafer carrier 210, wafer 205, and top ring 220 are assembled into a single unit. Top ring 220 may also help to prevent wafer 205 from moving.

FIG. 3b is a diagram illustrating an isometric view of wafer holding system 200. FIG. 3b illustrates another alternate embodiment of wafer carrier 210, wherein wafer carrier 210 does not feature alignment pillars. Since wafer carrier 210 does not have alignment pillars, wafer 205 may not include holes. A combination of vacuum holes in wafer carrier 210 and top ring 220 may be sufficient to prevent wafer 205 from moving as well as maintaining proper alignment. If there are no alignment pillars, then wafer carrier 210 may have indentations on its surface corresponding to the size of wafer 205. For example, if wafer 205 is a six (6) inch wafer, then wafer carrier 210 may have an indentation on its surface intended to hold six inch wafers.

FIG. 3c is a diagram illustrating a side view of wafer holding system 200, wherein wafer holding system 200 has been cut along a line through its middle. As shown in FIG. 3c, alignment pillars, such as alignment pillar 305 extends through the entirety of wafer 205 and into holes in top ring 220. Although shown to extend to a highest extent of top ring 220, the alignment pillars may extend just into top ring 220 or above top ring 220. The alignment pillars extending into top ring 220 may help to maintain integrity of wafer holding system 200 as a unit as wafer holding system 200 is moved around during fabrication.

FIG. 3d is a diagram illustrating an isometric view of wafer carrier 210. Wafer carrier 210 is shown to have three alignment pillars, such as alignment pillar 310. As discussed previously, wafer carrier 210 may have any number of alignment pillars, with a preferred number ranging between two and six.

FIG. 3e is a diagram of an isometric view of wafer holding system 200. As shown in FIG. 3e, wafer holding system 200 includes wafer carrier 210 and wafer 205. Missing from wafer holding system 200 is top ring 220 that is shown in other embodiments. A precise fit between wafer 205 and wafer carrier 210 may be able to eliminate a need for top ring 220. Alignment pillars in wafer carrier 210 may include a latching system to help ensure that wafer 205 does not separate from wafer carrier 210.

FIG. 3f is a diagram of a top view of wafer 205 and wafer carrier 210. As shown in FIG. 3f, rather than having holes in wafer 205 for alignment pillars to pass through, wafer 205 may have notches formed along the outer edge, such as notch 315. The notches formed along the outer edge of wafer 205 may line up with alignment pillars of wafer carrier 210, such as alignment pillar 320. By using notches rather than holes, the amount of unusable area on the surface of wafer 205 may be reduced. Although shown as being circular notches, notches of other profiles, such as oval, square, v-shaped, hexagonal, and so forth, may be used, with the shape being primarily dependent on the cross-sectional shape of the alignment pillar.

FIG. 3g is a diagram of a side cross-sectional view of wafer holding system 200. As shown in FIG. 3g, wafer holding system 200 includes wafer carrier 210 and wafer 205. Wafer carrier 210 includes an indentation 330 on its top surface. Indentation 330 may be used to hold wafer 205. Indentation 330 may be about equal to or slightly larger in diameter than wafer 205 to help ensure that alignment is maintained. Indentation 330 may have a depth that is about equal to or greater than the thickness of wafer 205. In an alternative embodiment, the depth of indentation 330 may be less than the thickness of wafer 205, but the depth should be sufficient to adequately hold wafer 205. Although not shown, wafer carrier 210 may or may not have vacuum holes to hold wafer 205 once wafer 205 is placed in indentation 330.

FIG. 3h is a diagram of a side cross-sectional view of wafer holding system 200, wherein wafer 205 is placed in indentation 330 of wafer carrier 210. Walls of indentation 330 may have a slope to help ensure centering of wafer 205 in wafer carrier 210. FIG. 3i is a diagram of a side cross-sectional view of wafer holding system 200 that includes a top ring 220 to help hold wafer 205 in indentation 330.

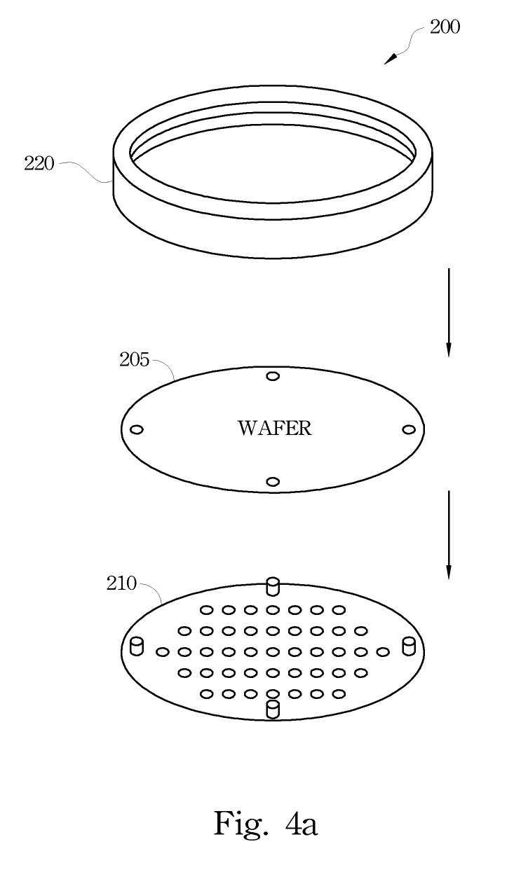

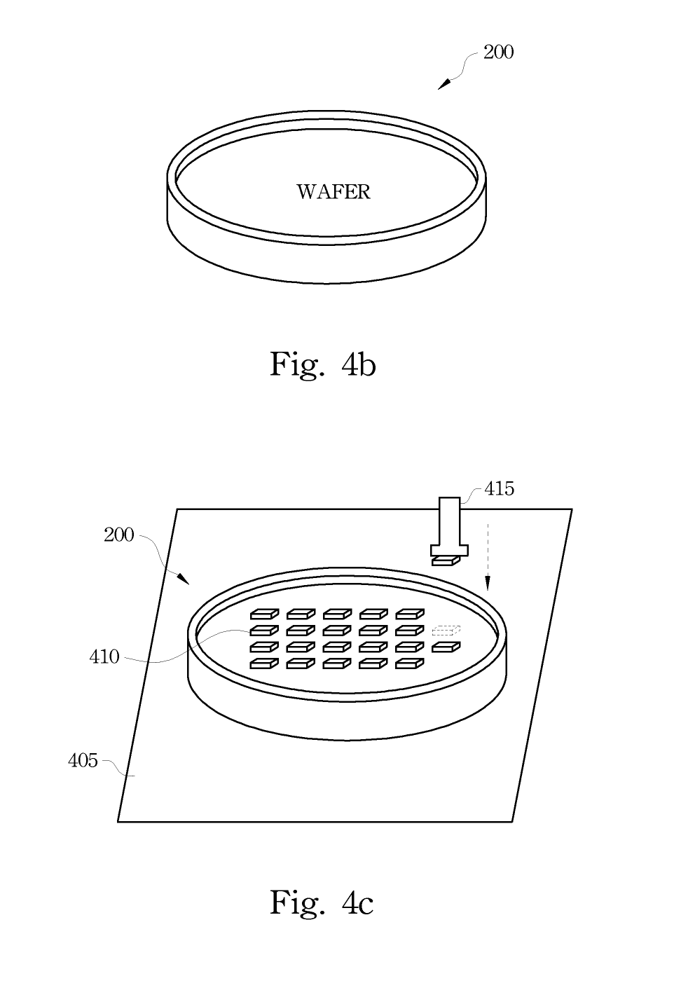

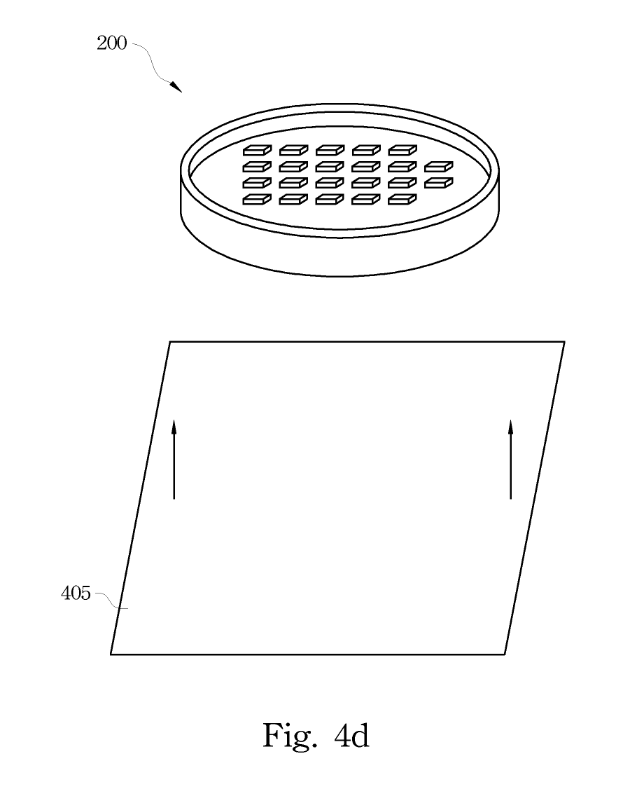

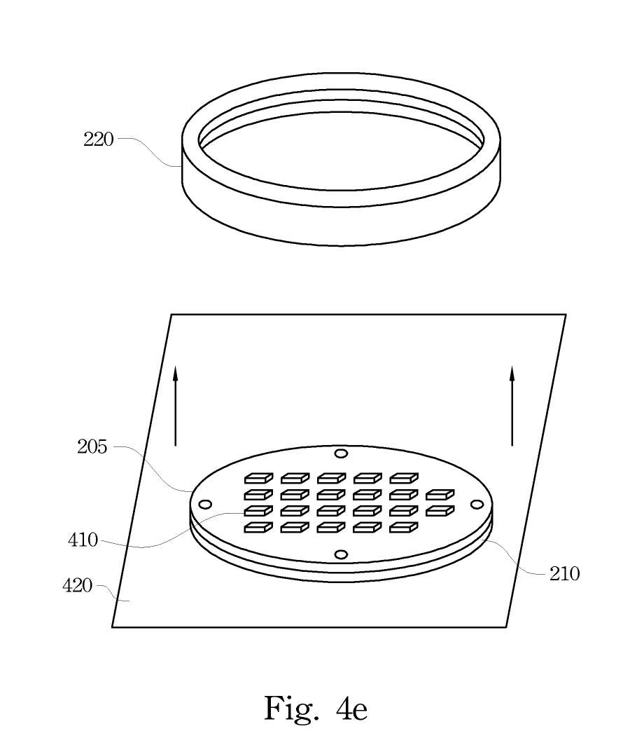

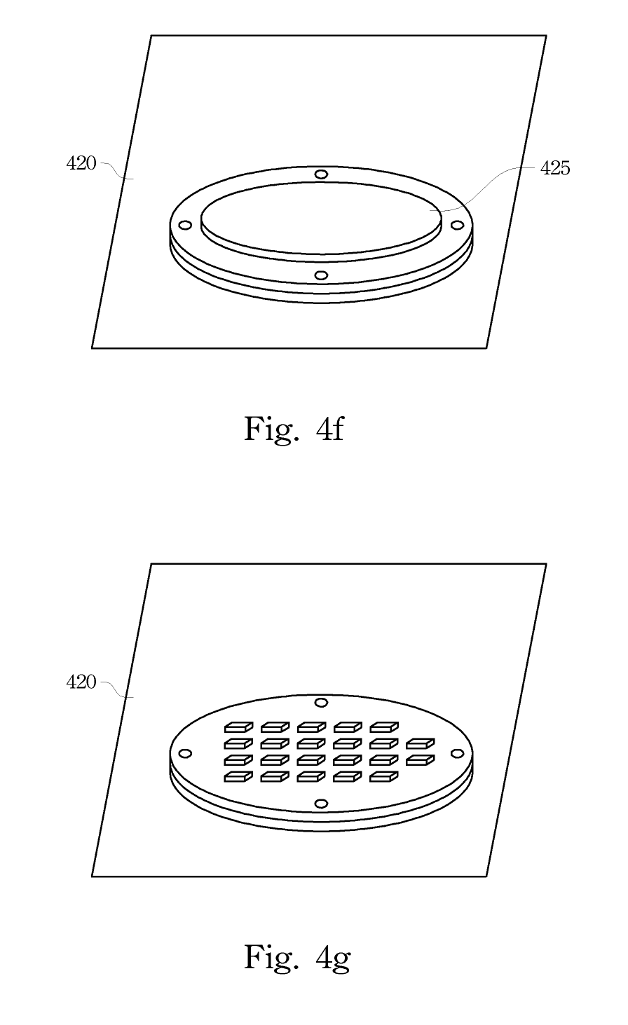

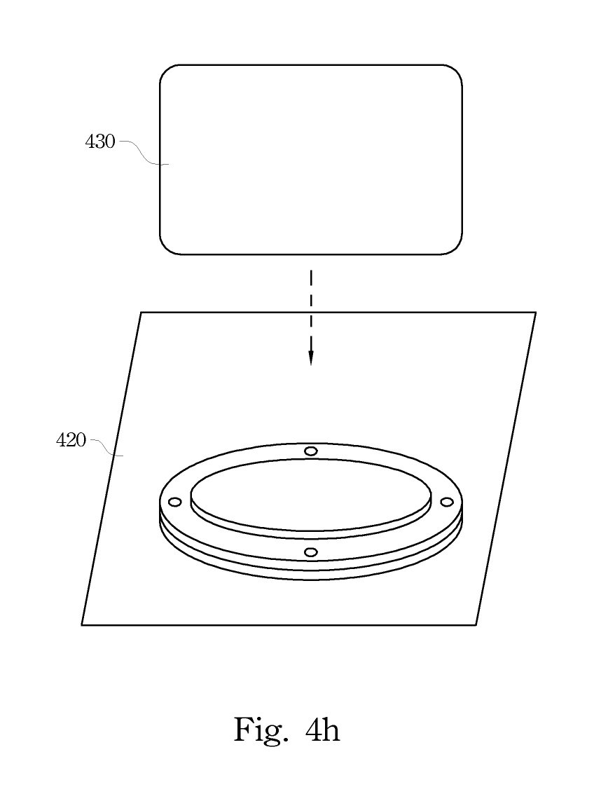

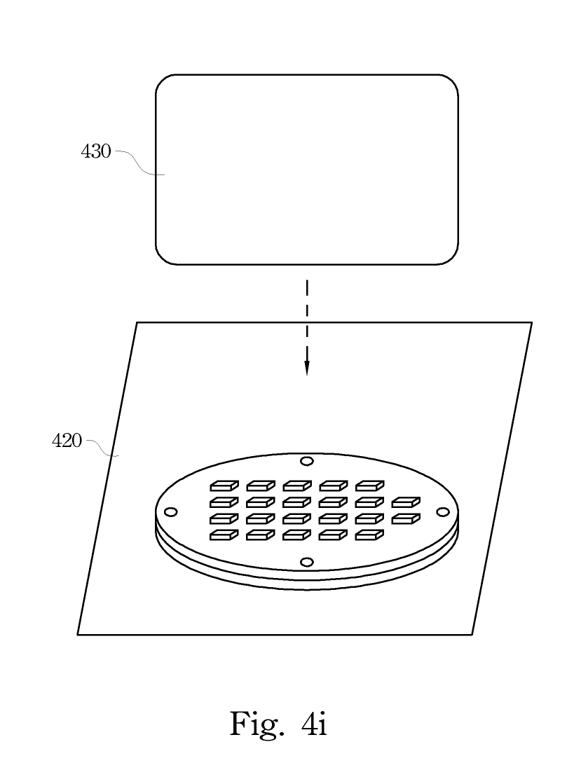

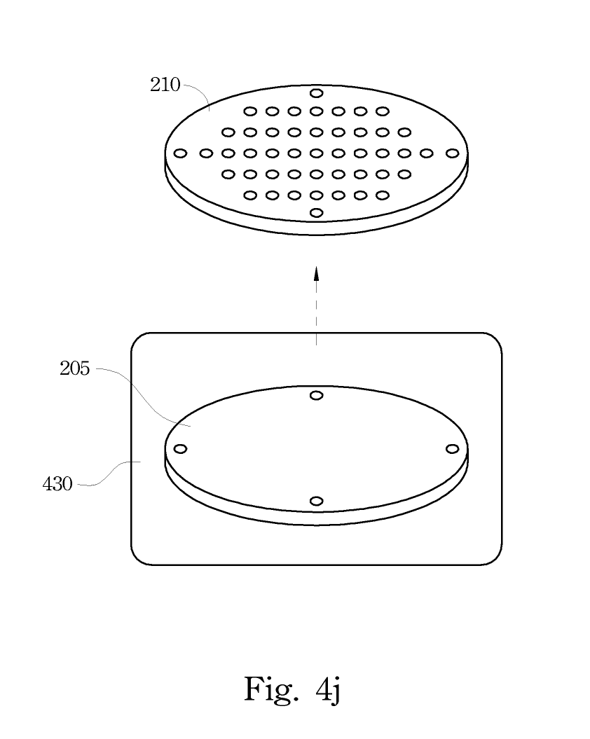

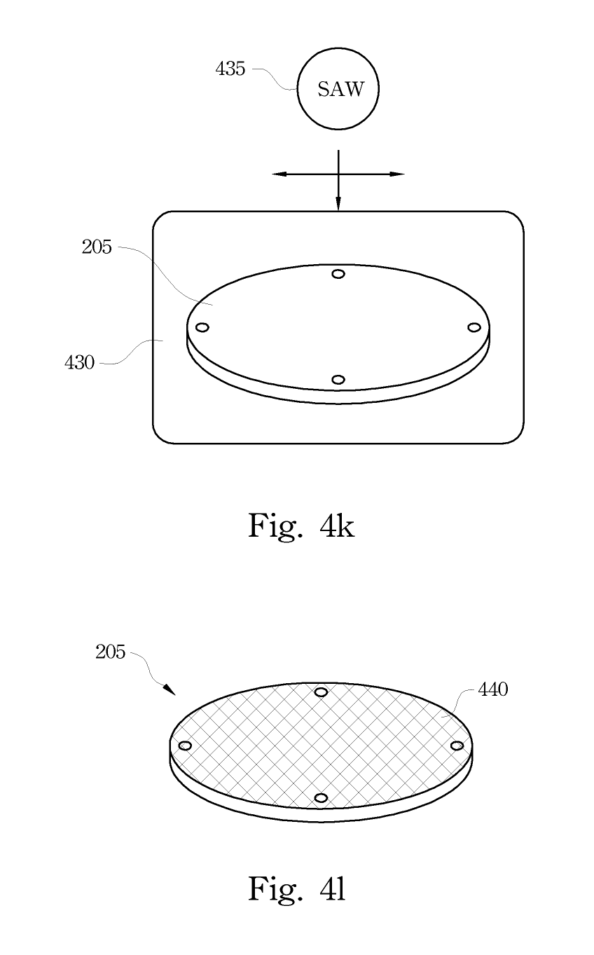

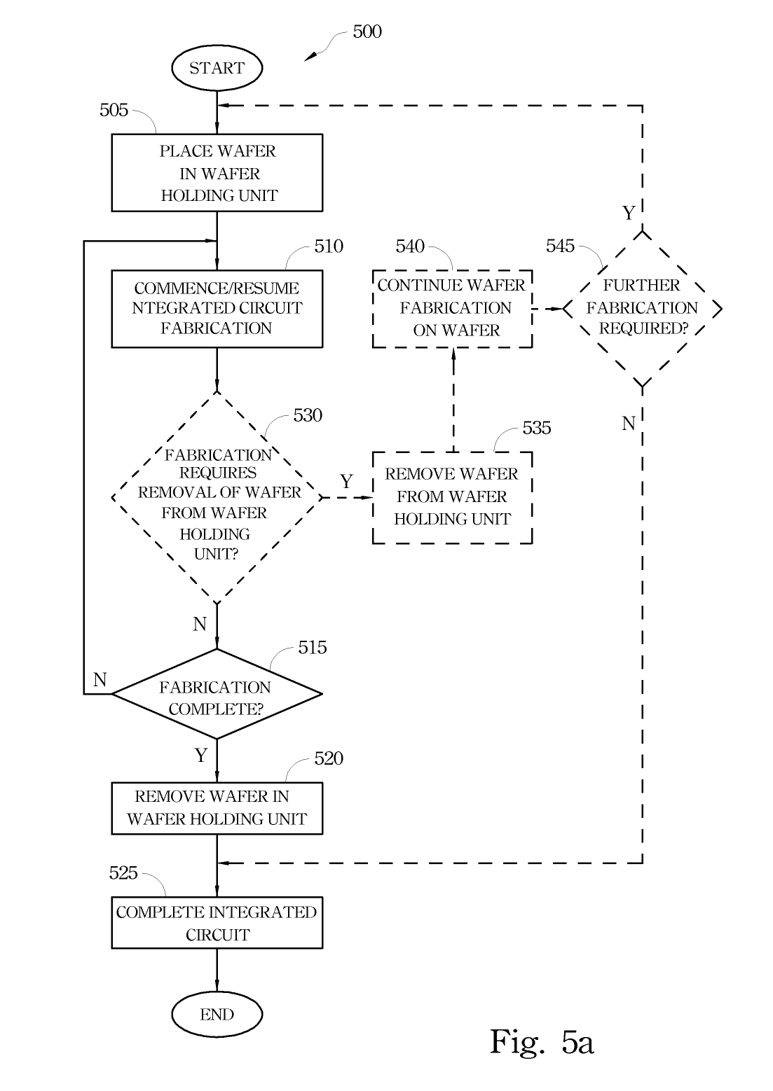

FIGS. 4a through 4l are diagrams illustrating the fabrication of integrated circuits using a top die bonding technique. As shown in FIG. 4a, wafer 205 is placed on wafer carrier 210 and then top ring 220 is placed over both wafer 205 and wafer carrier 210, turning wafer holding system 200 into a single unit, shown in FIG. 4b. In FIG. 4c, the diagram shows that wafer holding system 200 may then be placed on a vacuum stage 405 that may create a vacuum, thereby causing wafer holding system 200 to adhere to vacuum stage 405.

With wafer holding system 200 firmly positioned on vacuum stage 405, die containing integrated circuits, such as die 410 may be attached to wafer 205, which may already have integrated circuits formed on its surface. A ram 415 may be used to place die on the surface of wafer 205. Once the die placement is complete, the vacuum created on vacuum stage 405 may be stopped and wafer holding system 200 may be removed (shown in FIG. 4d).

FIG. 4e is a diagram showing wafer holding system 200 placed on another vacuum stage (molding vacuum stage 420), where top ring 220 may be removed from wafer holding system 200 leaving wafer 205 with dice 410 and wafer carrier 210. On molding vacuum stage 420, a wafer molding may be applied over wafer 205. FIG. 4f is a diagram of wafer 205 with molding 425 applied on its surface, while FIG. 4g is a diagram of wafer 205 without molding.

With or without molding, dicing tape 430 may be applied to the surface of wafer 205 (FIGS. 4h and 4i). With dicing tape 430 applied, wafer carrier 210 may be removed from wafer 205, leaving just wafer 205 attached to dicing tape 430. FIG. 4j is a diagram illustrating a bottom view of wafer 205 with dicing tape 430 attached to its top surface. Then, individual dies may be sawn from wafer 205 by a saw 435 (shown in FIG. 4k). Dicing tape 430 helps to keep wafer 205 together as the sawing takes place. Finally, FIG. 4l a diagram illustrating wafer 205 cut into a number of individual die, such as die 440, which may undergo further processing, such as packaging, or so forth.

Although the FIGS. 4a through 4l illustrate the fabrication of integrated circuits using top die bonding, wafer holding system 200 may be used in the fabrication of integrated circuits using a wide variety of techniques, including those that include multiple dies and those that do not. Therefore, the discussion of top die bonding should not be construed as being limiting to either the scope or the spirit of the embodiments.

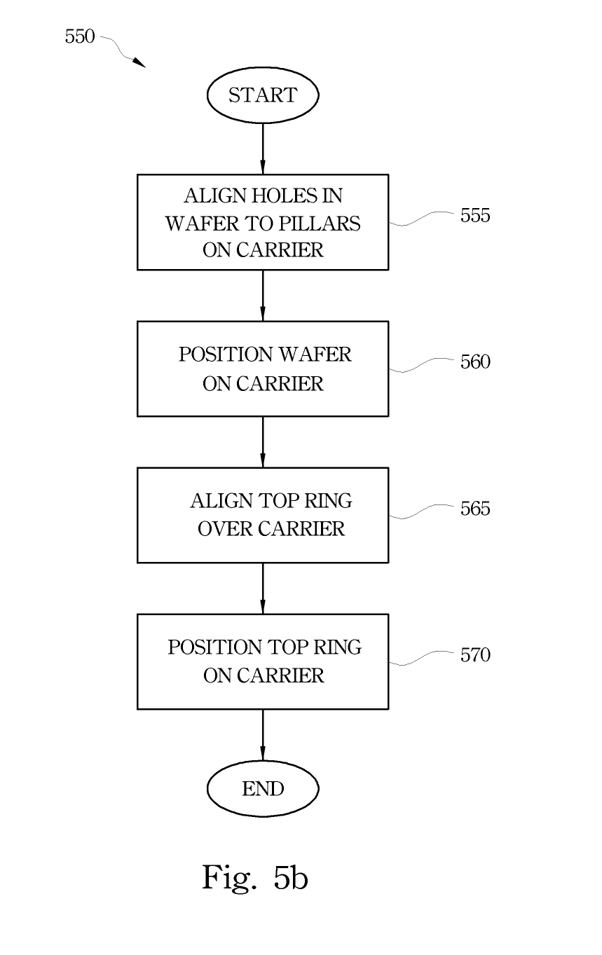

FIG. 5a is a flow diagram of the fabrication of an integrated circuit 500. The fabrication of an integrated circuit 500 may begin with a placement of a wafer, such as wafer 205, into a wafer holding unit (block 505). The wafer may be placed on a wafer carrier, such as wafer carrier 205, held in alignment by alignment pillars, a top ring, such as top ring 220, or a combination thereof.

FIG. 5b is a flow diagram of the placement of a wafer in a wafer holding unit 550. The placement of the wafer holding unit 550 may begin with aligning holes in the wafer with alignment pillars in the wafer carrier (block 555). With the holes aligned with the alignment pillars, the wafer may then be positioned on the wafer carrier (block 560). If the wafer carrier does not have alignment pillars, then the wafer may just need to be aligned with the wafer carrier. For example, the wafer may be centered in the wafer carrier.

With the wafer positioned in the wafer carrier, a top ring may then be aligned over the wafer and the wafer carrier (block 565). If the alignment pillars are intended to also align the top ring, then holes in the top ring may be aligned with the alignment pillars prior to the top ring being placed over the wafer and the wafer carrier (block 570).

Turning back now to FIG. 5a, after the wafer is in place in the wafer holding unit, fabrication of integrated circuits on the wafer may commence (block 510). Fabrication of integrated circuits on the wafer may include the use of typical photolithography, immersion lithography, and other techniques for creating the integrated circuits on the wafer. Additionally, fabrication may also include attaching substrates that also contain integrated circuits onto the wafer, and so forth.

A check may then be performed to determine if fabrication is complete (block 515). If fabrication is not complete, then the fabrication may return to block 510 to resume fabrication of integrated circuits on the wafer. Preferably, a check may be performed after each fabrication step. Alternatively, a check may be performed after a sequence of fabrication steps that do not require movement, alignment, and so on, of the wafer holding unit. If fabrication is complete, then the wafer may be removed from the wafer holding unit (block 520).

Removing the wafer from the wafer holding unit may involve removing the top ring, removing the wafer from the wafer carrier, or combinations thereof. With the wafer removed from the wafer holding unit, the integrated circuits on the wafer may be completed (block 525). Completing the integrated circuits may include cutting out individual dies, packaging the dies, and so forth. The fabrication of the integrated circuits may then terminate.

Depending on the fabrication process used to fabricate integrated circuits on the wafer, it may be necessary to remove the wafer from the wafer holding unit. For example, the fabrication process may involve the use of materials that are incompatible with the wafer carrier or the top ring, a fabrication process step may involve machinery not capable of handling the wafer holding unit due to its size, and so forth. Since the removal of the wafer from the wafer holding unit is fabrication process dependent, it may be optional.

An optional check may be performed to determine if it is necessary to remove the wafer from the wafer holding unit (block 530). If it is not necessary to remove the wafer from the wafer holding unit, then a check may be performed to determine if fabrication is complete (block 515). If it is necessary to remove the wafer from the wafer holding unit, then the wafer may be removed from the wafer holding unit (block 535) and fabrication of the integrated circuits may continue on the wafer alone (block 540). The fabrication of the integrated circuits on the wafer alone may continue for as long as needed.

Then, another check may be performed to determine if further fabrication is required (block 545). If additional fabrication is required, then the wafer may be placed back in the wafer holding unit (block 505) and the fabrication of integrated circuits on the wafer may continue. If additional fabrication is not required, then the integrated circuits on the wafer may be completed (block 525). Completing the integrated circuits may include cutting out individual dies, packaging the dies, and so forth. The fabrication of the integrated circuits may then terminate.

Although the embodiments and their advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A wafer holding system comprising:
a wafer carrier configured to hold the wafer at a specified alignment, the wafer carrier having an alignment mechanism to hold the wafer in the specified alignment; and
a top ring disposed on a top surface of the wafer and of the wafer carrier, the top ring configured to hold the wafer and the wafer carrier together as a single unit.

2. The wafer holding system of claim 1, wherein the alignment mechanism comprises a plurality of alignment pillars.

3. The wafer holding system of claim 2, wherein the plurality of alignment pillars are disposed about a periphery of the wafer carrier.

4. The wafer holding system of claim 1, wherein the wafer has a plurality of holes on its surface, wherein there is at least one hole per alignment pillar.

5. The wafer holding system of claim 4, wherein each hole has substantially the same cross-section as a corresponding alignment pillar.

6. The wafer holding system of claim 4, wherein the top ring has a plurality of holes on its surface, wherein there is at least one hole per alignment pillar.

7. The wafer holding system of claim 2, wherein the wafer has a plurality of notches formed on its outer edge, wherein there is at least one notch per alignment pillar.

8. The wafer holding system of claim 1, wherein the alignment mechanism comprises a plurality of vacuum holes formed through the wafer carrier.

9. The wafer holding system of claim 8, wherein the plurality of vacuum holes are distributed about evenly over the wafer carrier.

10. The wafer holding system of claim 1, wherein the alignment mechanism comprises an indentation on a top surface of the wafer carrier, the indentation to hold the wafer.

11. The wafer holding system of claim 10, wherein the indentation is larger than or equal in size to the wafer.

12. A system comprising:
a base unit formed of a first material having a coefficient of thermal expansion (CTE) substantially equal to that of a wafer disposed on a top surface of the base unit, the base unit having an alignment mechanism to maintain a specified alignment of the wafer; and
a ring having a cylindrical flange extending at least part way down over the base unit to fit over the wafer and the base unit, and a lip formed around a top surface of the ring to prevent the base unit from extending more into the ring than specified, the ring formed of a second material having a CTE about equal to that of the wafer.

13. The system of claim 12, wherein the alignment mechanism comprises a plurality of alignment pillars formed in an annular ring about an outer band of the base unit, with each alignment pillar extending perpendicularly from a top surface of the base unit.

14. The system of claim 13, wherein the wafer has a plurality of holes formed in an annular ring about an exclusion band, wherein each hole is slightly larger than an alignment pillar, and wherein there are at least as many holes as there are alignment pillars.

15. The system of claim 13, wherein the ring has a plurality of ring holes formed in its top surface, and wherein there are at least as many ring holes as there are alignment pillars.

16. The system of claim 12, wherein the alignment mechanism comprises a circular indentation on the surface of the base unit, and wherein the circular indentation is at least as large as the wafer.

17. The system of claim 12, wherein the alignment mechanism comprises a plurality of vacuum holes formed through the base unit, and wherein the plurality of vacuum holes are distributed over the surface of the base unit.

18. A wafer for use with a wafer carrier having an alignment mechanism to hold the wafer in a specified alignment, the wafer comprising a circular disc with a plurality of alignment openings formed in an annular ring located at an outer periphery of the wafer, wherein the alignment pillars at least in part pass through the alignment openings when the wafer is placed onto the wafer carrier to hold the wafer in alignment, wherein each alignment opening is slightly larger than an alignment pillar, and wherein there are at least as many alignment openings as there are alignment pillars.

19. The wafer of claim 18, wherein the alignment openings are holes.

20. The wafer of claim 18, wherein the alignment openings are notches formed on an outer edge of the wafer.
